(19) United States
(12) Patent Application Publication
(10) Pub. No.: US 2021/0360790 A1
(43) Pub. Date: Nov. 18, 2021

(54) SUBSTRATE COMBINING STRUCTURE, SUBSTRATE COMBINING SYSTEM AND SUBSTRATE COMBINING METHOD

(71) Applicant: ASTI GLOBAL INC., TAIWAN, Taichung City (TW)

(72) Inventor: CHIEN-SHOU LIAO, New Taipei City (TW)

(21) Appl. No.: 17/315,338

(22) Filed: May 9, 2021

(30) Foreign Application Priority Data
May 12, 2020 (TW) 109115664

(51) Int. Cl. H05K 1/14; H05K 1/03

(52) U.S. Cl. CPC H05K 1/142; H05K 1/0306

(57) ABSTRACT

A substrate combining structure, a substrate combining system, and a substrate combining method are provided. The substrate combining structure includes a first glass substrate, a second glass substrate, a glass connecting layer, and a patterned circuit layer. The glass connecting layer is connected between the first and the second glass substrates. The patterned circuit layer includes a first circuit layer disposed on the first glass substrate, a second circuit layer disposed on the second glass substrate, and a circuit connecting layer connected between the first and the second circuit layers. The first and the second glass substrates and the glass connecting layer are matched with each other to form a glass substrate assembly having a larger carrying area, and the first and the second circuit layers and the circuit connecting layer are matched with each other to form a patterned circuit layer having a larger layout area.

### CROSS-REFERENCE TO RELATED PATENT APPLICATION

This application claims the benefit of priority to Taiwan Patent Application No. 109115664, filed on May 12, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a combination structure, a combination system and a combination method, and more particularly to a substrate combining structure, a substrate combining system, and a substrate combining method.

### BACKGROUND OF THE DISCLOSURE

In the related art, a conventional print circuit board (PCB) can serve as a carrier for carrying a circuit layout, but the conventional PCB cannot be combined (connected) with another conventional PCB.

### SUMMARY OF THE DISCLOSURE

In response to the above-referenced technical inadequacy, the present disclosure provides a substrate combining structure, a substrate combining system, and a substrate combining method.

In one aspect, the present disclosure provides a substrate combining structure including a first glass substrate, a second glass substrate, a glass connecting layer, and a patterned circuit layer. The glass connecting layer is connected between the first glass substrate and the second glass substrate. The patterned circuit layer includes a first circuit layer disposed on the first glass substrate, a second circuit layer disposed on the second glass substrate, and a circuit connecting layer connected between the first circuit layer and the second circuit layer.

In another aspect, the present disclosure provides a substrate combining system including a substrate carrying device, a connection layer forming device, and a circuit layer forming device. The substrate carrying device is used for carrying a first glass substrate and a second glass substrate. The connection layer forming device is disposed above the substrate carrying device for forming a glass connecting layer between the first glass substrate and the second glass substrate. The circuit layer forming device is disposed above the substrate carrying device for forming a circuit connecting layer that is connected between a first circuit layer and a second circuit layer.

In yet another aspect, the present disclosure provides a substrate combining method including the steps of: providing a first glass substrate and a second glass substrate, forming a glass connecting layer between the first glass substrate and the second glass substrate; and then forming a circuit connecting layer between a first circuit layer and a second circuit layer.

Therefore, by virtue of “the glass connecting layer being connected between the first glass substrate and the second glass substrate” and “the patterned circuit layer including a first circuit layer disposed on the first glass substrate, a second circuit layer disposed on the second glass substrate, and a circuit connecting layer connected between the first circuit layer and the second circuit layer”, the first glass substrate, the second glass substrate, and the glass connecting layer can be matched (or connected or conjoined) with each other to form a glass substrate assembly having a larger carrying area, and the first circuit layer, the second circuit layer, and the circuit connecting layer can be matched (or connected or conjoined) with each other to form a patterned circuit layer having a larger layout area.

Moreover, by virtue of “the connection layer forming device being disposed above the substrate carrying device for forming a glass connecting layer between the first glass substrate and the second glass substrate” and “the circuit layer forming device being disposed above the substrate carrying device for forming a circuit connecting layer connected between a first circuit layer and a second circuit layer”, the first glass substrate, the second glass substrate, and the glass connecting layer can be matched (or connected or conjoined) with each other to form a glass substrate assembly having a larger carrying area, and the first circuit layer, the second circuit layer, and the circuit connecting layer can be matched (or connected or conjoined) with each other to form a patterned circuit layer having a larger layout area.

Furthermore, by virtue of “forming a glass connecting layer between the first glass substrate and the second glass substrate” and “forming a circuit connecting layer between a first circuit layer and a second circuit layer”, the first glass substrate, the second glass substrate, and the glass connecting layer can be matched (or connected or conjoined) with each other to form a glass substrate assembly having a larger carrying area, and the first circuit layer, the second circuit layer, and the circuit connecting layer can be matched (or connected or conjoined) with each other to form a patterned circuit layer having a larger layout area.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a substrate combining method according to the present disclosure;

FIG. 2 is a schematic cross-sectional view of step S102 of a substrate combining method according to a first embodiment of the present disclosure;

FIG. 3 is a schematic cross-sectional view of step S104 of the substrate combining method according to the first embodiment of the present disclosure;

FIG. 4 is a schematic cross-sectional view of step S106 of the substrate combining method according to the first embodiment of the present disclosure;

FIG. 5 is a schematic cross-sectional view of step S108 of the substrate combining method according to the first embodiment of the present disclosure;

FIG. 6 is a schematic cross-sectional view of step S110 of the substrate combining method according to the first embodiment of the present disclosure;

FIG. 7 is a schematic cross-sectional view of a bridging wire crossing over a glass connecting material and being electrically connected between a first circuit layer and a second circuit layer according to a second embodiment of the present disclosure;

FIG. 8 is a schematic cross-sectional view of step S200 of a substrate combining method according to a third embodiment of the present disclosure;

FIG. 9 is a schematic cross-sectional view of step S202 of the substrate combining method according to the third embodiment of the present disclosure;

FIG. 10 is a schematic cross-sectional view of step S204 of the substrate combining method according to the third embodiment of the present disclosure;

FIG. 11 is a schematic cross-sectional view of step S206 of the substrate combining method according to the third embodiment of the present disclosure;

FIG. 12 is a schematic cross-sectional view of step S208 of the substrate combining method according to the third embodiment of the present disclosure;

FIG. 13 is a schematic cross-sectional view of a glass connecting material formed on a first glass substrate by a connection layer forming device according to a fourth embodiment of the present disclosure;

FIG. 14 is a schematic cross-sectional view of a glass connecting layer connected between a top surface of the first glass substrate and a bottom surface of a second glass substrate according to the fourth embodiment of the present disclosure; and

FIG. 15 is a schematic cross-sectional view of a circuit connecting layer disposed on the first glass substrate and the second glass substrate by a circuit layer forming device according to the fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

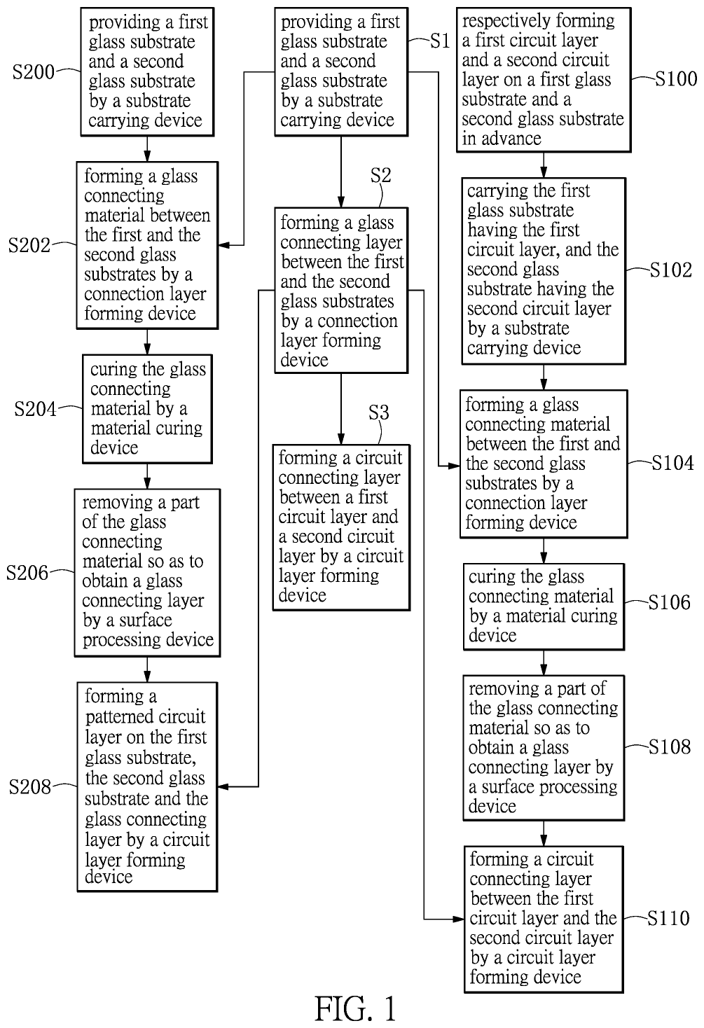

Referring to FIG. 1 to FIG. 15, the present disclosure provides a substrate combining structure S including a first glass substrate 1, a second glass substrate 2, a glass connecting layer 3, and a patterned circuit layer 4. The glass connecting layer 3 is connected between the first glass substrate 1 and the second glass substrate 2. The patterned circuit layer 4 includes a first circuit layer 41 disposed on the first glass substrate 1, a second circuit layer 42 disposed on the second glass substrate 2, and a circuit connecting layer 43 (such as a line connecting layer) connected between the first circuit layer 41 and the second circuit layer 42.

Referring to FIG. 1 to FIG. 15, the present disclosure provides a substrate combining system including a substrate carrying device D1, a connection layer forming device D2, and a circuit layer forming device D5. The substrate carrying device D1 is used for carrying a first glass substrate 1 and a second glass substrate 2. The connection layer forming device D2 is disposed above the substrate carrying device D1 for forming a glass connecting layer 3 between the first glass substrate 1 and the second glass substrate 2. The circuit layer forming device D5 is disposed above the substrate carrying device D1 for forming a circuit connecting layer 43 that is connected between a first circuit layer 41 and a second circuit layer 42.

Referring to FIG. 1 to FIG. 15, the present disclosure provides a substrate combining method including the steps of: providing a first glass substrate 1 and a second glass substrate 2 by a substrate carrying device D1 (step S1), forming a glass connecting layer 3 between the first glass substrate 1 and the second glass substrate 2 by a connection layer forming device D2 (step S2); and then forming a circuit connecting layer 43 between a first circuit layer 41 and a second circuit layer 42 by a circuit layer forming device D5 (step S3).

### First Embodiment

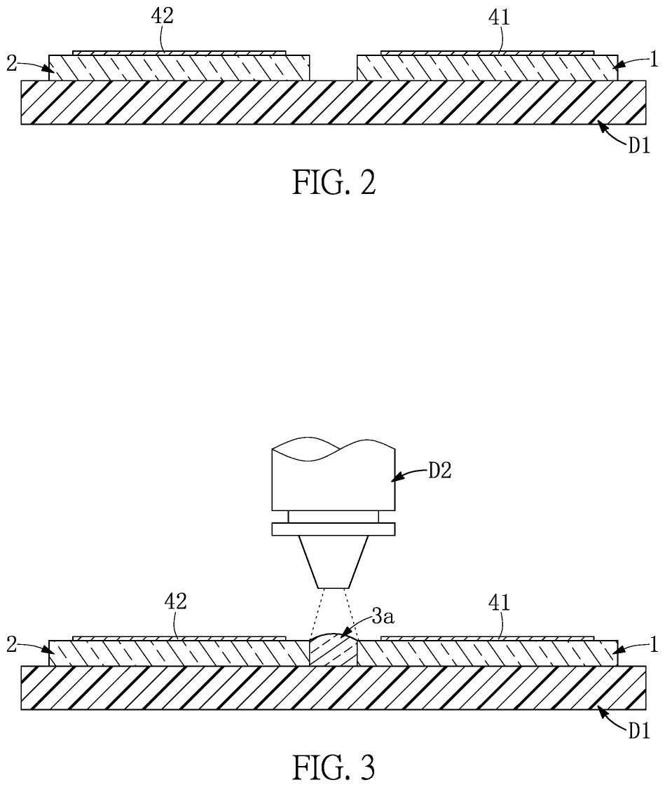

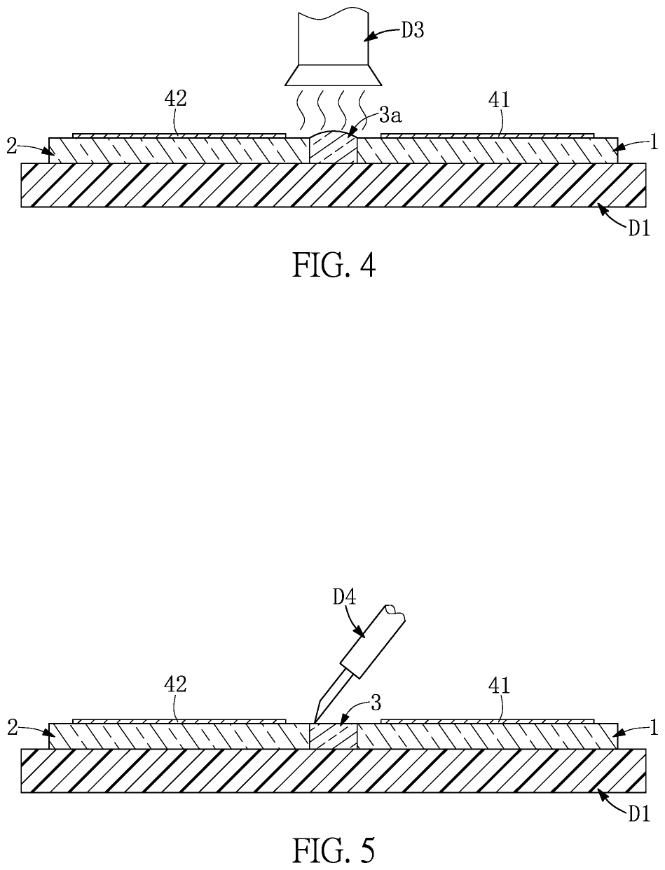

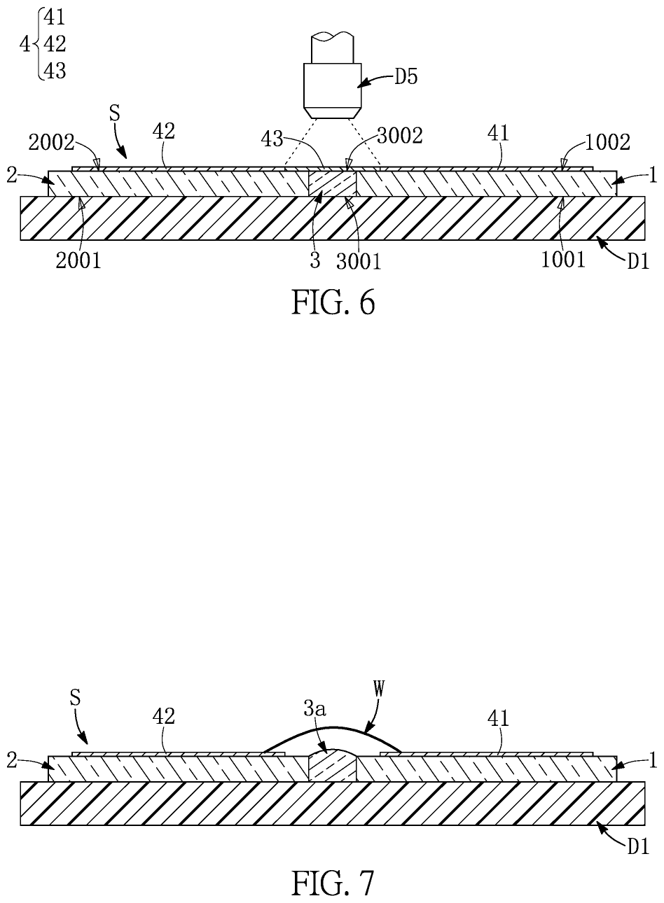

Referring to FIG. 1 to FIG. 6, a first embodiment of the present disclosure provides a substrate combining method including the steps of: firstly, referring to FIG. 1 and FIG. 2, respectively forming a first circuit layer 41 and a second circuit layer 42 on a first glass substrate 1 and a second glass substrate 2 in advance (step S100); next, referring to FIG. 1 and FIG. 2, carrying the first glass substrate 1 having the first circuit layer 41, and the second glass substrate 2 having the second circuit layer 42 by a substrate carrying device D1 (step S102); then, referring to FIG. 1 and FIG. 3, forming a glass connecting material 3a between the first glass substrate 1 and the second glass substrate 2 by a connection layer forming device D2 (step S104); afterwards, referring to FIG. 1 and FIG. 4, curing (or hardening) the glass connecting material 3a by a material curing device D3 (step S106); next, referring to FIG. 1, FIG. 4 and FIG. 5, removing a part of the glass connecting material 3a so as to obtain a glass connecting layer 3 by a surface processing device D4 (step S108); and then referring to FIG. 1 and FIG. 6, forming a circuit connecting layer 43 between the first circuit layer 41 and the second circuit layer 42 by a circuit layer forming device D5 (step S110), so as to complete manufacture of a substrate combining structure S.

More particularly, referring to FIG. 2 to FIG. 6, the first embodiment of the present disclosure provides a substrate combining system including a substrate carrying device D1, a connection layer forming device D2, a material curing device D3, a surface processing device D4, and a circuit layer forming device D5. However, the material curing device D3 and the surface processing device D4 are both nonessential processing devices, so that the material curing device D3 and the surface processing device D4 can be omitted in the substrate combining system of the first embodiment of the present disclosure.

For example, referring to FIG. 2 and FIG. 3, the first glass substrate 1 having the first circuit layer 41 and the second glass substrate 2 having the second circuit layer 42 can be respectively carried by the substrate carrying device D1, and the substrate carrying device D1 can be a fixed carrying device or a movable carrying device. In addition, the connection layer forming device D2 is disposed above the substrate carrying device D1 for forming a glass connecting material 3a between the first glass substrate 1 and the second glass substrate 2, and the connection layer forming device D2 can be a material extruding device or a material spraying device. It should be noted that the glass connecting material 3a can be glass glue, adhesive glue or any adhesive material having a glass component (such as silicon dioxide). However, the aforementioned description is merely an example and is not meant to limit the scope of the present disclosure.

For example, referring to FIG. 4 and FIG. 5, the material curing device D3 is disposed above the substrate carrying device D1 for curing (or hardening) a glass connecting material 3a, and the surface processing device D4 is disposed above the substrate carrying device D1 for removing a part of the glass connecting material 3a, so as to obtain a glass connecting layer 3. In addition, the material curing device D3 can be a laser heating device or a baking device, and the surface processing device D4 can be a physical processing device (such as a cutting tool) or a laser processing device. However, the aforementioned description is merely an example and is not meant to limit the scope of the present disclosure.

It should be noted that the material curing device D3 and the surface processing device D4 are two nonessential processing devices, so that the material curing device D3 and the surface processing device D4 can be omitted in the substrate combining system of the first embodiment of the present disclosure. For example, when a capacity of a receiving space between the first glass substrate 1 and the second glass substrate 2 can be obtained in advance, the connection layer forming device D2 can be used to provide a sufficient amount of glass connection material 3a to exactly fill up the receiving space between the first glass substrate 1 and the second glass substrate 2, so that a glass connecting layer 3 can be obtained by curing the glass connecting material 3a directly. That is to say, the glass connecting layer 3 can also be directly formed between the first glass substrate 1 and the second glass substrate 2 by using only the connection layer forming device D2 (or a connection material providing device) in the first embodiment of the present disclosure. However, the aforementioned description is merely an example and is not meant to limit the scope of the present disclosure.

For example, referring to FIG. 6, the circuit layer forming device D5 is disposed above the substrate carrying device D1 for forming a circuit connecting layer 43 that is connected between a first circuit layer 41 and a second circuit layer 42. In addition, the circuit layer forming device D5 can be a conductive line forming device (or a conductive line printing device), or a semiconductor processing device, or a compound mechanism including a metal forming device and an engraving device. It should be noted that the circuit connecting layer 43 provided by the circuit layer forming device D5 includes a plurality of conductive lines, and each of the conductive lines can be electrically connected between a corresponding conductive terminal of the first circuit layer 41 and a corresponding conductive terminal of the second circuit layer 42. However, the aforementioned description is merely an example and is not meant to limit the scope of the present disclosure.

More particularly, referring to FIG. 6, the first embodiment of the present disclosure provides a substrate combining structure S including a first glass substrate 1, a second glass substrate 2, a glass connecting layer 3, and a patterned circuit layer 4. The glass connecting layer 3 is connected between the first glass substrate 1 and the second glass substrate 2. The patterned circuit layer 4 includes a first circuit layer 41 disposed on the first glass substrate 1, a second circuit layer 42 disposed on the second glass substrate 2, and a circuit connecting layer 43 connected between the first circuit layer 41 and the second circuit layer 42.

For example, referring to FIG. 6, no through holes are formed on the first glass substrate 1 and the second glass substrate 2, so that the first glass substrate 1 and the second glass substrate 2 can have a complete internal structure free of through holes. In addition, a bottom surface 1001 of the first glass substrate 1, a bottom surface 2001 of the second glass substrate 2, and a bottom surface 3001 of the glass connecting layer 3 can be flush with each other, and a top surface 1002 of the first glass substrate 1, a top surface 2002 of the second glass substrate 2, and a top surface 3002 of the glass connecting layer 3 can be flush with each other. Moreover, the circuit connecting layer 43 is disposed on the first glass substrate 1, the second glass substrate 2, and the glass connecting layer 3, and the circuit connecting layer 43 is connected between a side of the first circuit layer 41 and a side of the second circuit layer 42. It should be noted that a first connection interface is defined (or formed) between the first circuit layer 41 and the circuit connecting layer 43, a second connection interface is defined (formed) between the second circuit layer 42 and the circuit connecting layer 43, so that the first circuit layer 41, the circuit connecting layer 43 and the second circuit layer 42 can be sequentially connected to form a combined-type patterned circuit layer. However, the aforementioned description is merely an example and is not meant to limit the scope of the present disclosure.

### Second Embodiment

Referring to FIG. 7, a second embodiment of the present disclosure provides a substrate combining structure S including a first glass substrate 1, a second glass substrate 2, a glass connecting material 3a (such as a raw glass connecting layer) and a bridging wire W (or a crossing wire). Comparing FIG. 7 with FIG. 6, the biggest difference between the second embodiment and the first embodiment is as follows: in the second embodiment, after the glass connecting material 3a (as shown in the first embodiment of FIG. 3 and FIG. 4) is formed, the bridging wire W can cross over the glass connecting material 3a (without contacting the glass connecting material 3a) and electrically connect between the first circuit layer 41 and the second circuit layer 42.

### Third Embodiment

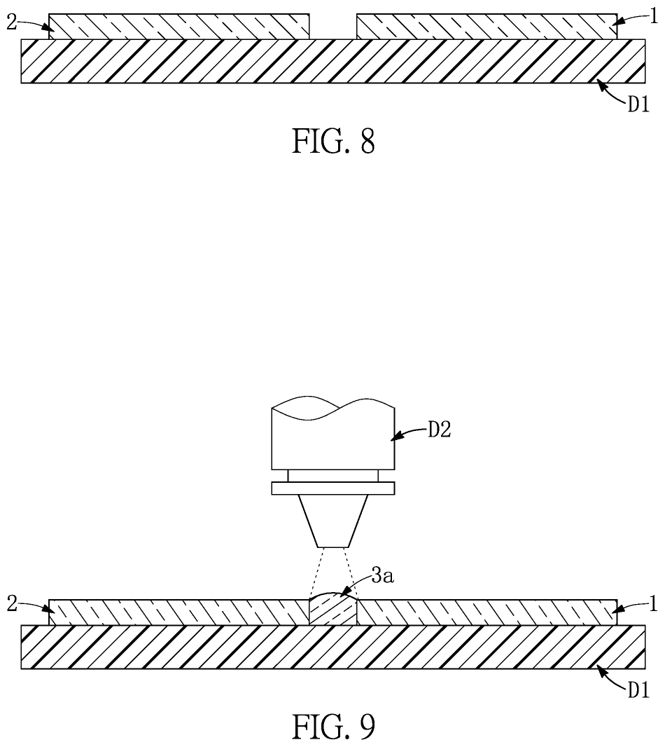

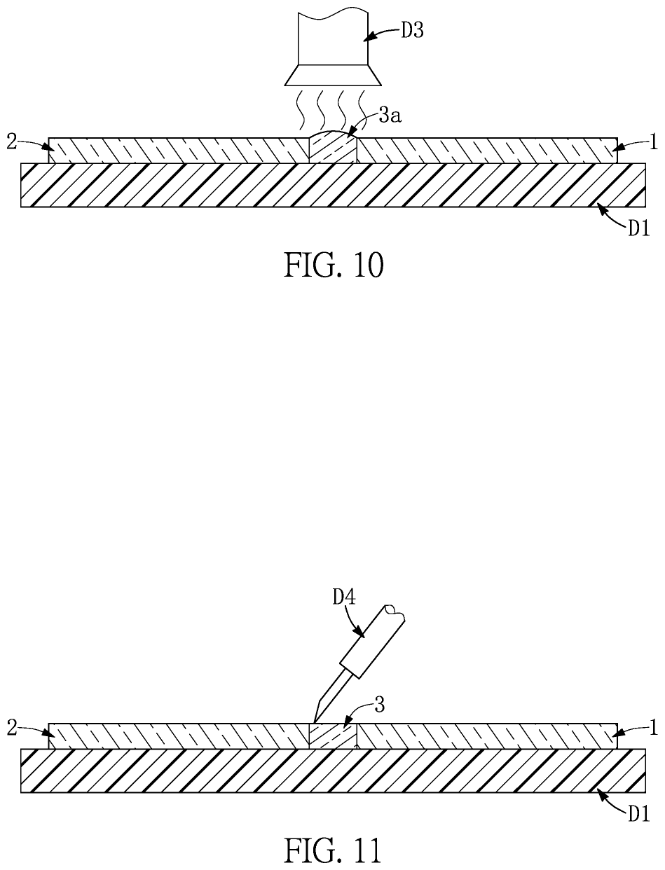

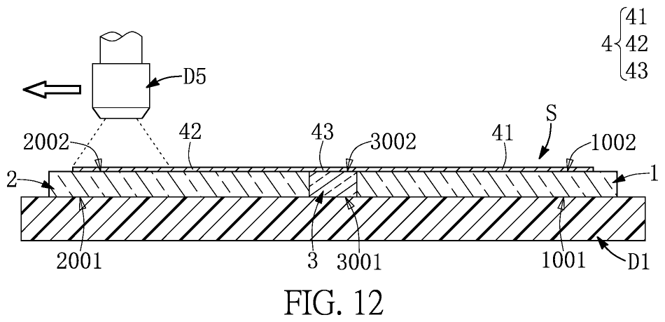

Referring to FIG. 1, and FIG. 8 to FIG. 12, a third embodiment of the present disclosure provides a substrate combining method including: firstly, referring to FIG. 1 and FIG. 8, providing a first glass substrate 1 and a second glass substrate 2 by a substrate carrying device D1 (step S200); next, referring to FIG. 1 and FIG. 9, forming a glass connecting material 3a between the first glass substrate 1 and the second glass substrate 2 by a connection layer forming device D2 (step S202); then, referring to FIG. 1 and FIG. 10, curing (or hardening) the glass connecting material 3a by a material curing device D3 (step S204); afterwards, referring to FIG. 1, FIG. 10 and FIG. 11, removing a part of the glass connecting material 3a so as to obtain a glass connecting layer 3 by a surface processing device D4 (step S206); and then referring to FIG. 1 and FIG. 12, forming a patterned circuit layer 4 on the first glass substrate 1, the second glass substrate 2 and the glass connecting layer 3 by a circuit layer forming device D5 (step S208). In addition, the patterned circuit layer 4 includes a first circuit layer 41 disposed on the first glass substrate 1, a second circuit layer 42 disposed on the second glass substrate 2, and a circuit connecting layer 43 connected between the first circuit layer 41 and the second circuit layer 42, so as to complete manufacture of a substrate combining structure S.

More particularly, referring to FIG. 8 to FIG. 12, the third embodiment of the present disclosure provides a substrate combining system including a substrate carrying device D1, a connection layer forming device D2, a material curing device D3, a surface processing device D4, and a circuit layer forming device D5. However, the material curing device D3 and the surface processing device D4 are two nonessential processing devices, so that the material curing device D3 and the surface processing device D4 can be omitted in the substrate combining system of the third embodiment of the present disclosure.

For example, referring to FIG. 8 and FIG. 9, the first glass substrate 1 and the second glass substrate 2 can be respectively carried by the substrate carrying device D1, and the substrate carrying device D1 can be a fixed carrying device or a movable carrying device. In addition, the connection layer forming device D2 is disposed above the substrate carrying device D1 for forming a glass connecting material 3a between the first glass substrate 1 and the second glass substrate 2, and the connection layer forming device D2 can be a material extruding device or a material spraying device. It should be noted that the glass connecting material 3a can be glass glue, adhesive glue or any adhesive material having a glass component (such as silicon dioxide). However, the aforementioned description is merely an example and is not meant to limit the scope of the present disclosure.

For example, referring to FIG. 10 and FIG. 11, the material curing device D3 is disposed above the substrate carrying device D1 for curing (or hardening) a glass connecting material 3a, and the surface processing device D4 is disposed above the substrate carrying device D1 for removing a part of the glass connecting material 3a, so as to obtain a glass connecting layer 3. In addition, the material curing device D3 can be a laser heating device or a baking device, and the surface processing device D4 can be a physical processing device (such as a cutting tool) or a laser processing device. However, the aforementioned description is merely an example and is not meant to limit the scope of the present disclosure.

It should be noted that the material curing device D3 and the surface processing device D4 are both nonessential processing devices, so that the material curing device D3 and the surface processing device D4 can be omitted in the substrate combining system of the third embodiment of the present disclosure. For example, when a capacity of a receiving space between the first glass substrate 1 and the second glass substrate 2 can be obtained in advance, the connection layer forming device D2 can be used to provide a sufficient amount of glass connection material 3a to exactly fill up the receiving space between the first glass substrate 1 and the second glass substrate 2, so that a glass connecting layer 3 can be obtained by curing the glass connecting material 3a directly. That is to say, the glass connecting layer 3 can also be directly formed between the first glass substrate 1 and the second glass substrate 2 by using only the connection layer forming device D2 (or a connection material providing device) in the third embodiment of the present disclosure. However, the aforementioned description is merely an example and is not meant to limit the scope of the present disclosure.

For example, referring to FIG. 12, the circuit layer forming device D5 is disposed above the substrate carrying device D1 for forming a patterned circuit layer 4 including a first circuit layer 41, a second circuit layer 42, and a circuit connecting layer 43. In addition, the circuit layer forming device D5 can be a conductive line forming device (or a conductive line printing device), or a semiconductor processing device, or a compound mechanism including a metal forming device and an engraving device. It should be noted that the first circuit layer 41, the circuit connecting layer 43, and the second circuit layer 42 (or the second circuit layer 42, the circuit connecting layer 43, and the first circuit layer 41) can be sequentially formed by the circuit layer forming device D5, so as to form an integral patterned circuit layer (or an integrated patterned circuit layer). However, the aforementioned description is merely an example and is not meant to limit the scope of the present disclosure.

More particularly, referring to FIG. 12, the third embodiment of the present disclosure provides a substrate combining structure S including a first glass substrate 1, a second glass substrate 2, a glass connecting layer 3, and a patterned circuit layer 4. The glass connecting layer 3 is connected between the first glass substrate 1 and the second glass substrate 2. The patterned circuit layer 4 includes a first circuit layer 41 disposed on the first glass substrate 1, a second circuit layer 42 disposed on the second glass substrate 2, and a circuit connecting layer 43 connected between the first circuit layer 41 and the second circuit layer 42.

For example, referring to FIG. 12, no through holes are formed on the first glass substrate 1 and the second glass substrate 2, so that the first glass substrate 1 and the second glass substrate 2 can have a complete internal structure without any through holes. In addition, a bottom surface 1001 of the first glass substrate 1, a bottom surface 2001 of the second glass substrate 2, and a bottom surface 3001 of the glass connecting layer 3 can be flush with each other, and a top surface 1002 of the first glass substrate 1, a top surface 2002 of the second glass substrate 2, and a top surface 3002 of the glass connecting layer 3 can be flush with each other. Moreover, the circuit connecting layer 43 is disposed on the first glass substrate 1, the second glass substrate 2, and the glass connecting layer 3, and the circuit connecting layer 43 is connected between a side of the first circuit layer 41 and a side of the second circuit layer 42. It should be noted that the first circuit layer 41, the circuit connecting layer 43, and the second circuit layer 42 are sequentially connected to form an integral patterned circuit layer (or an integrated patterned circuit layer), so that there is no connection interface defined (or formed) between the first circuit layer 41 and the circuit connecting layer 43 and between the second circuit layer 42 and the circuit connecting layer 43. However, the aforementioned description is merely an example and is not meant to limit the scope of the present disclosure.

### Fourth Embodiment

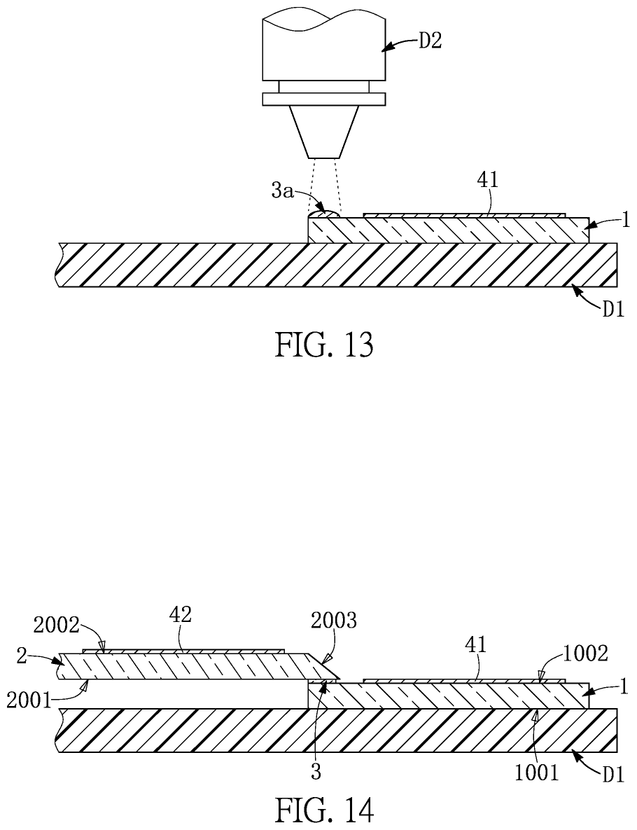

Referring to FIG. 13 to FIG. 15, a fourth embodiment of the present disclosure provides a substrate combining structure S including a first glass substrate 1, a second glass substrate 2, a glass connecting layer 3, and a patterned circuit layer 4. The difference between the fourth embodiment and the first (or the second or the third) embodiment is as follows: in the fourth embodiment, after a glass connecting material 3a is formed on the first glass substrate 1 by a connection layer forming device D2, the second glass substrate 2 can be disposed on the first glass substrate 1 through the glass connecting material 3a, and then the glass connecting layer 3 can be formed by curing the glass connecting material 3a. Therefore, the glass connecting layer 3 can be connected between a top surface 1002 of the first glass substrate 1 and a bottom surface 2001 of the second glass substrate 2, and the circuit connecting layer 43 can be disposed on the first glass substrate 1 and the second glass substrate 2 by a circuit layer forming device D5, but the circuit connecting layer 43 cannot be disposed on the glass connecting layer 3 (that is to say, the glass connecting layer 3 cannot be covered by the circuit connecting layer 43).

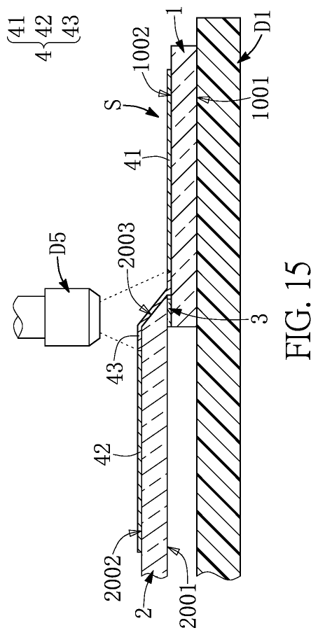

For example, referring to FIG. 14 and FIG. 15, the second glass substrate 2 has an inclined surface 2003, and the circuit connecting layer 43 can be disposed on a top surface 1002 of the first glass substrate 1, a top surface 2002 of the second glass substrate 2, and the inclined surface 2003 of the second glass substrate 2. In addition, the first circuit layer 41, the circuit connecting layer 43, and the second circuit layer 42 can be sequentially connected to form a combined-type patterned circuit layer. Alternatively, the fourth embodiment can have the same configuration as the third embodiment, and the first circuit layer 41, the circuit connecting layer 43, and the second circuit layer 42 can be sequentially connected to form an integral patterned circuit layer (or an integrated patterned circuit layer). However, the aforementioned description is merely an example and is not meant to limit the scope of the present disclosure.

### Beneficial Effects of the Embodiments

In conclusion, by virtue of “the glass connecting layer 3 being connected between the first glass substrate 1 and the second glass substrate 2” and “the patterned circuit layer 4 including a first circuit layer 41 disposed on the first glass substrate 1, a second circuit layer 42 disposed on the second glass substrate 2, and a circuit connecting layer 43 connected between the first circuit layer 41 and the second circuit layer 42”, the first glass substrate 1, the second glass substrate 2, and the glass connecting layer 3 can be matched (or connected or conjoined) with each other to form a glass substrate assembly having a larger carrying area, and the first circuit layer 41, the second circuit layer 42, and the circuit connecting layer 43 can be matched (or connected or conjoined) with each other to form a patterned circuit layer 4 having a larger layout area (or a larger circuit region).

Moreover, by virtue of “the connection layer forming device D2 being disposed above the substrate carrying device D1 for forming a glass connecting layer 3 between the first glass substrate 1 and the second glass substrate 2” and “the circuit layer forming device D5 being disposed above the substrate carrying device D1 for forming a circuit connecting layer 43 connected between a first circuit layer 41 and a second circuit layer 42”, the first glass substrate 1, the second glass substrate 2, and the glass connecting layer 3 can be matched (or connected or conjoined) with each other to form a glass substrate assembly having a larger carrying area, and the first circuit layer 41, the second circuit layer 42 and the circuit connecting layer 43 can be matched (or connected or conjoined) with each other to form a patterned circuit layer 4 having a larger layout area (or a larger circuit region).

Furthermore, by virtue of “forming a glass connecting layer 3 between the first glass substrate 1 and the second glass substrate 2” and “forming a circuit connecting layer 43 between a first circuit layer 41 and a second circuit layer 42”, the first glass substrate 1, the second glass substrate 2, and the glass connecting layer 3 can be matched (or connected or conjoined) with each other to form a glass substrate assembly having a larger carrying area, and the first circuit layer 41, the second circuit layer 42, and the circuit connecting layer 43 can be matched (or connected or conjoined) with each other to form a patterned circuit layer 4 having a larger layout area (or a larger circuit region).

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A substrate combining structure, comprising:
a first glass substrate;
a second glass substrate;
a glass connecting layer connected between the first glass substrate and the second glass substrate; and
a patterned circuit layer including a first circuit layer disposed on the first glass substrate, a second circuit layer disposed on the second glass substrate, and a circuit connecting layer connected between the first circuit layer and the second circuit layer.

2. The substrate combining structure according to claim 1, wherein a first connection interface is defined between the first circuit layer and the circuit connecting layer, a second connection interface is defined between the second circuit layer and the circuit connecting layer, so that the first circuit layer, the circuit connecting layer, and the second circuit layer are sequentially connected to form a combined-type patterned circuit layer.

3. The substrate combining structure according to claim 2, wherein no through hole is formed on the first glass substrate and the second glass substrate, a bottom surface of the first glass substrate, a bottom surface of the second glass substrate, and a bottom surface of the glass connecting layer are flush with one another, and a top surface of the first glass substrate, a top surface of the second glass substrate, and a top surface of the glass connecting layer are flush with one another.

4. The substrate combining structure according to claim 2, wherein the circuit connecting layer is disposed on the first glass substrate, the second glass substrate, and the glass connecting layer, and the circuit connecting layer is connected between a side of the first circuit layer and a side of the second circuit layer.

5. The substrate combining structure according to claim 1, wherein the first circuit layer, the circuit connecting layer, and the second circuit layer are sequentially connected to form an integral patterned circuit layer, so that no connection interface is defined between the first circuit layer and the circuit connecting layer and between the second circuit layer and the circuit connecting layer.

6. The substrate combining structure according to claim 5, wherein no through hole is formed on the first glass substrate and the second glass substrate, a bottom surface of the first glass substrate, a bottom surface of the second glass substrate, and a bottom surface of the glass connecting layer are flush with one another, and a top surface of the first glass substrate, a top surface of the second glass substrate, and a top surface of the glass connecting layer are flush with one another.

7. The substrate combining structure according to claim 5, wherein the circuit connecting layer is disposed on the first glass substrate, the second glass substrate, and the glass connecting layer, and the circuit connecting layer is connected between a side of the first circuit layer and a side of the second circuit layer.

8. The substrate combining structure according to claim 1, wherein the glass connecting layer is connected between a top surface of the first glass substrate and a bottom surface of the second glass substrate, and the circuit connecting layer is disposed on the first glass substrate and the second glass substrate and is not disposed on the glass connecting layer.

9. The substrate combining structure according to claim 1, wherein the second glass substrate has an inclined surface, and the circuit connecting layer is disposed on a top surface of the first glass substrate, a top surface of the second glass substrate, and the inclined surface of the second glass substrate.

10. The substrate combining structure according to claim 1, wherein the first circuit layer, the circuit connecting layer, and the second circuit layer are sequentially connected to form a combined-type patterned circuit layer or an integral patterned circuit layer.

11. A substrate combining system, comprising:
a substrate carrying device for carrying a first glass substrate and a second glass substrate;
a connection layer forming device disposed above the substrate carrying device for forming a glass connecting layer between the first glass substrate and the second glass substrate; and
a circuit layer forming device disposed above the substrate carrying device for forming a circuit connecting layer connected between a first circuit layer and a second circuit layer.

12. The substrate combining system according to claim 11, further comprising:
a material curing device disposed above the substrate carrying device for curing a glass connecting material that is formed between the first glass substrate and the second glass substrate.

13. The substrate combining system according to claim 12, further comprising:
a surface processing device disposed above the substrate carrying device for removing a part of the glass connecting material, so as to obtain the glass connecting layer.

14. The substrate combining system according to claim 11, wherein the first circuit layer, the circuit connecting layer, and the second circuit layer are sequentially connected to form a combined-type patterned circuit layer by the circuit layer forming device, so that a first connection interface is defined between the first circuit layer and the circuit connecting layer, and a second connection interface is defined between the second circuit layer and the circuit connecting layer.

15. The substrate combining system according to claim 11, wherein the first circuit layer, the circuit connecting layer, and the second circuit layer are sequentially connected to form an integral patterned circuit layer by the circuit layer forming device, so that no connection interface is defined between the first circuit layer and the circuit connecting layer and between the second circuit layer and the circuit connecting layer.

16. A substrate combining method, comprising:
providing a first glass substrate and a second glass substrate;
forming a glass connecting layer between the first glass substrate and the second glass substrate; and
forming a circuit connecting layer between a first circuit layer and a second circuit layer.

17. The substrate combining method according to claim 16, wherein, before the step of providing the first glass substrate and the second glass substrate, the first circuit layer and the second circuit layer are respectively disposed on the first glass substrate and the second glass substrate in advance.

18. The substrate combining method according to claim 16, wherein the step of forming the glass connecting layer between the first glass substrate and the second glass substrate further includes:
forming a glass connecting material between the first glass substrate and the second glass substrate;
curing the glass connecting material; and
removing a part of the glass connecting material so as to obtain the glass connecting layer.

19. The substrate combining method according to claim 16, wherein the first circuit layer, the circuit connecting layer, and the second circuit layer are sequentially connected to form a combined-type patterned circuit layer, so that a first connection interface is defined between the first circuit layer and the circuit connecting layer, and a second connection interface is defined between the second circuit layer and the circuit connecting layer.

20. The substrate combining method according to claim 16, wherein the first circuit layer, the circuit connecting layer, and the second circuit layer are sequentially connected to form an integral patterned circuit layer, so that no connection interface is defined between the first circuit layer and the circuit connecting layer and between the second circuit layer and the circuit connecting layer.
